(19) United States
(12) Patent Application Publication
(10) Pub. No.: US 2014/0049248 A1
(43) Pub. Date: Feb. 20, 2014

(54) SPARK DETECTION DEVICE CAPABLE OF DETECTING CHARACTERISTICS OF A SPARK SIGNAL

(71) Applicant: Prolific Technology Inc., Taipei City (TW)

(72) Inventors: Chih-Shiun Lu, Hsinchu County (TW); Chia-Chang Hsu, Hsinchu County (TW); Ching-Tan Lin, Miaoli County (TW)

(21) Appl. No.: 13/910,134

(22) Filed: Jun. 5, 2013

(30) Foreign Application Priority Data
Aug. 17, 2012 (TW) 101129912

(51) Int. Cl. G01R 19/00

(52) U.S. Cl. CPC G01R 19/00
USPC 324/76.39; 324/76.11

(57) ABSTRACT

A spark detection device includes a sensing element and a comparing element. The sensing element is for sensing a spark signal to generate a sensing signal. A first end of the comparing element is coupled to the sensing element, and a second end of the comparing element is for receiving a threshold signal. The comparing element is for generating an output signal at an output end of the comparing element by performing a comparing operation according to the sensing signal and the threshold signal.

### BACKGROUND OF THE INVENTION

1. Field of the Invention

The present invention relates to a spark detection device, and more particularly, to a spark detection device capable of detecting characteristics of a spark signal.

2. Description of the Prior Art

Spark signals are voltage signals with high potential occurred in a very short time. The spark signals may easily crash electronic devices or damage components of the electronic devices. Therefore, detecting occurrence of the spark signals is a very important topic in the electronics industry. Please refer to FIG. 1. FIG. 1 is a diagram showing a spark detection circuit of the prior art. The spark detection circuit 100 of the prior art comprises a resistor R coupled to a ground end G, an inductor L coupled to the resistor R, and a transistor switch S. A first end t1 of the transistor switch S is coupled to a voltage source VCC, a second end t2 of the transistor switch S is coupled to the ground end G, and a control end tc of the transistor switch S is coupled to the inductor L. The transistor switch S is turned on and off according to a voltage level of the control end tc. When the voltage level of the control end tc is at a logic high level, the transistor switch S is turned on; and when the voltage level of the control end tc is at a logic low level, the transistor switch S is turned off.

Generally the electronic device is arranged with a spark protection unit at a signal input end, such that the spark signal may be inputted to the electronic device through the ground end, or the spark signal may be electromagnetically sensed to generate on an electromagnetic sensing unit (such as the inductor). When the spark signal is not occurred, the voltage level of the control end tc is equal to a voltage level of the ground end G, that is, the voltage level of the control end tc is at the logic low level, such that the transistor switch S is turned off. When the ground end G receives the spark signal or the inductor L senses the spark signal, a voltage signal Vs is generated at the control end tc, that is, the voltage level of the control end tc is at the logic high level, such that the transistor switch S is turned on to further output an output signal Vout at an output end out of the spark detection circuit 100, for notifying occurrence of the spark signal.

However, according to the above arrangement, the spark detection circuit 100 of the prior art can only detect whether the spark signal is occurred according to on and off states of the transistor switch S. The spark detection circuit 100 of the prior art cannot detect characteristics of the spark signal such as voltage level, energy level, and occurrence frequency. Therefore, the spark detection circuit 100 of the prior art is limited during use.

### SUMMARY OF THE INVENTION

The present invention provides a spark detection device capable of detecting characteristics of a spark signal. The spark detection device comprises a sensing element and a comparing element. The sensing element is for sensing a spark signal to generate a sensing signal. A first end of the comparing element is coupled to the sensing element. A second end of the comparing element is for receiving a threshold signal. The comparing element is for generating an output signal at an output end of the comparing element by performing a comparing operation according to the sensing signal and the threshold signal.

In contrast to the prior art, the spark detection device of the present invention can utilize different types of sensing elements for sensing the spark signal, and detecting characteristics of the spark signal according to a comparing result of the comparing element. Therefore, the spark detection device of the present invention can not only detect the occurrence of the spark signal, but also detect the characteristics of voltage level, energy level and frequency of the spark signal, so as to increase flexibility during use.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing a spark detection circuit of the prior art.

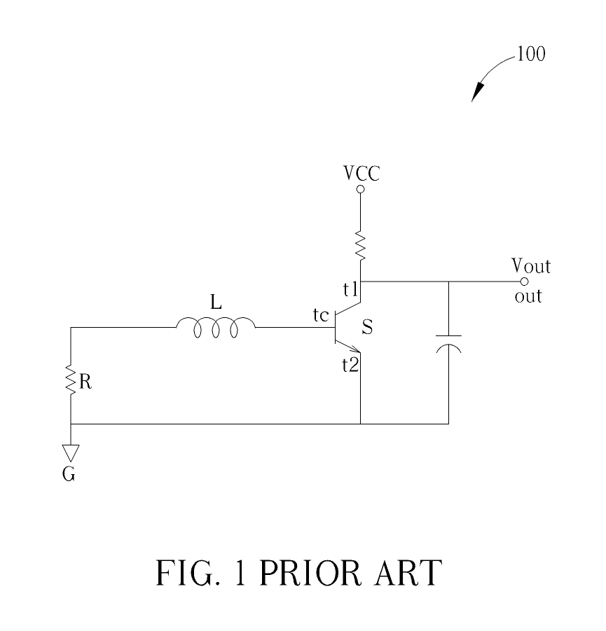

FIG. 2 is a diagram showing a first embodiment a spark detection device of the present invention.

FIG. 3 is a diagram showing a second embodiment the spark detection device of the present invention.

FIG. 4 is a diagram showing a third embodiment the spark detection device of the present invention.

FIG. 5 is a diagram showing a fourth embodiment the spark detection device of the present invention.

FIG. 6 is a functional block diagram of the spark detection device of the present invention.

FIG. 7 is another functional block diagram of the spark detection device of the present invention.

### DETAILED DESCRIPTION

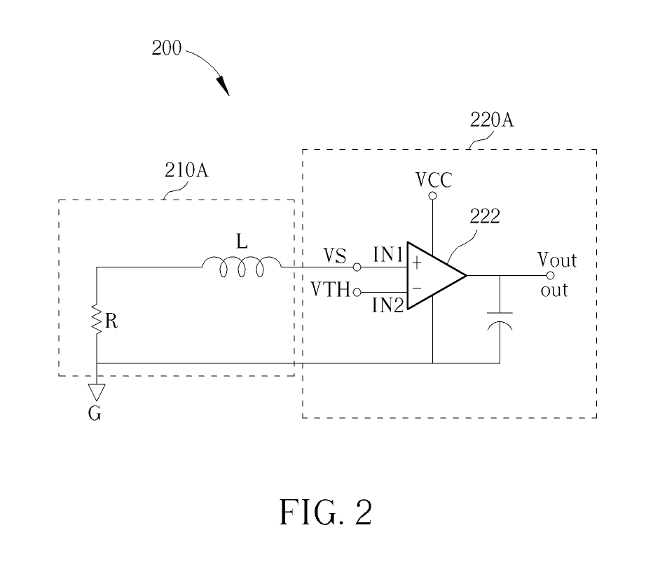

Please refer to FIG. 2. FIG. 2 is a diagram showing a first embodiment a spark detection device of the present invention. As shown in FIG. 2, the spark detection device 200 of the present invention comprises a sensing element 210A and a comparing element 220A. The sensing element 210A comprises a resistor R coupled to a ground end G, and an inductor L (or other electromagnetic sensing unit) coupled to the resistor R. The comparing element 220A comprises a comparator 222. A first input end IN1 of the comparing element 220A is coupled to the inductor L, and a second input end IN2 of the comparing element 220A is for receiving a threshold signal VTH. The comparing element 220A is for generating an output signal Vout at an output end out of the comparing element 220A by performing a comparing operation according to a sensing signal VS generated by the sensing element 210A and the threshold signal VTH. For example, when the ground end G receives the spark signal or the inductor L senses the spark signal, the inductor L generates a corresponding voltage signal Vs (that is the sensing signal) at the first input end IN1 of the comparing element 220A. The comparing element 220A then compares the sensing signal VS with the threshold signal VTH by the comparator 222. When the sensing signal VS is greater than the threshold signal VTH, the comparing element 220A generates the output signal Vout at the output end out, for notifying occurrence of the spark signal, and a voltage level of the spark signal is greater than a predetermined threshold value.

According to the above arrangement, the spark detection device 200 can detect the spark signal with the voltage level greater than the predetermined threshold value and generate the output signal Vout according to predetermined magnitude of the threshold signal. Other spark signals with voltage levels smaller than the threshold value are neglected.

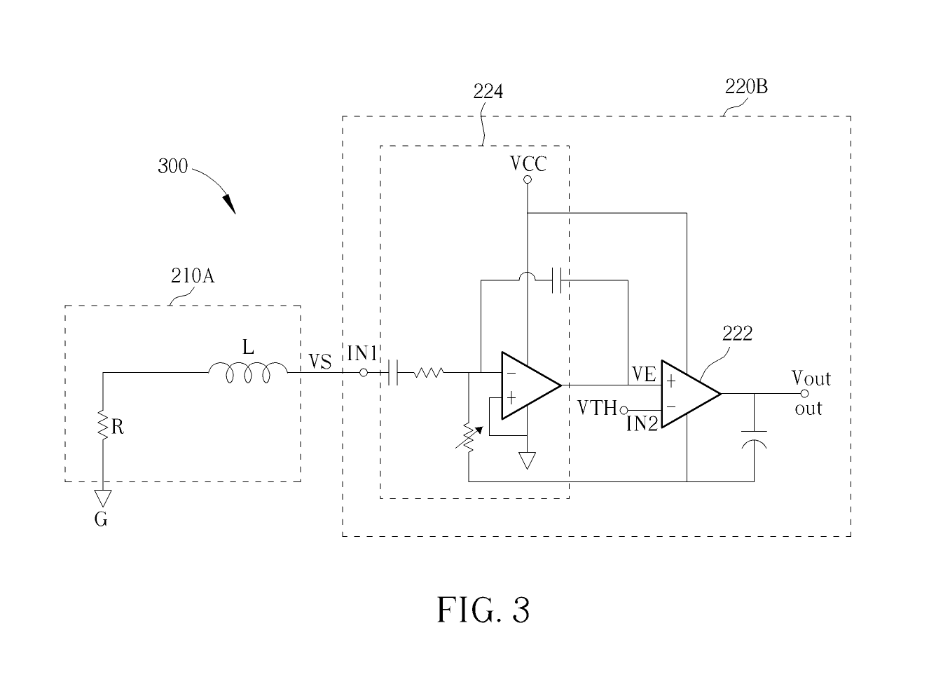

Please refer to FIG. 3. FIG. 3 is a diagram showing a second embodiment the spark detection device of the present invention. As shown in FIG. 3, the sensing element 210A of the spark detection device 300 comprises a resistor R coupled to a ground end G, and an inductor L (or other electromagnetic sensing unit) coupled to the resistor R. The comparing element 220A of the spark detection device 300 comprises an integrator circuit 224 and a comparator 222 coupled to the integrator circuit 224. A first input end IN1 of the comparing element 220B is coupled to the inductor L, and a second input end IN2 of the comparing element 220B is for receiving the threshold signal VTH. When the ground end G receives the spark signal or the inductor L senses the spark signal, the inductor L generates a corresponding voltage signal Vs (that is the sensing signal) at the first input end IN1 of the comparing element 220B. The comparing element 220B then utilizes the integrator circuit 224 to perform an integration operation to the sensing signal for generating a corresponding energy level signal VE. Thereafter, the comparing element 220B compares the energy level signal VE with the threshold signal VTH by the comparator 222. When the energy level signal VE is greater than the threshold signal VTH, the comparing element 220A generates the output signal Vout at the output end out, for notifying occurrence of the spark signal, and a energy level of the spark signal is greater than a predetermined threshold value.

According to the above arrangement, the spark detection device 300 can detect the spark signal with the energy level greater than the predetermined threshold value and generate the output signal Vout according to predetermined magnitude of the threshold signal. Other spark signals with energy levels smaller than the threshold value are neglected.

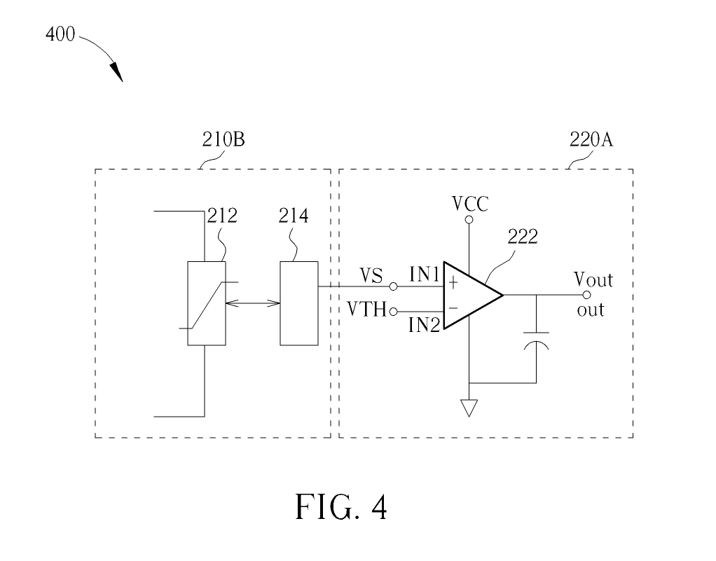

Please refer to FIG. 4. FIG. 4 is a diagram showing a third embodiment the spark detection device of the present invention. As shown in FIG. 4, the sensing element 210B of the spark detection device 400 comprises a spark bypass unit 212 and a temperature sensing unit 214. The spark bypass unit 212 is for allowing the spark signal passing through. The temperature sensing unit 214 is for sensing temperature of the spark bypass unit 212 to generate the corresponding sensing signal VS when the spark signal passing through the spark bypass unit 212. The comparing element 220A comprises a comparator 222. A first input end IN1 of the comparing element 220A is coupled to the temperature sensing unit 214, and a second input end IN2 of the comparing element 220A is for receiving the threshold signal VTH. When the spark signal passes through the spark bypass unit 212, the temperature of the spark bypass unit 212 is increased, and the temperature sensing unit 214 senses the temperature of the spark bypass unit 212 to generate a corresponding sensing signal VS. The comparing element 220A then compares the sensing signal VS with the threshold signal VTH by the comparator 222. When the sensing signal VS is greater than the threshold signal VTH, the comparing element 220A generates the output signal Vout at the output end out, for notifying occurrence of the spark signal, and the temperature of the spark bypass unit 212 is greater than a predetermined threshold value.

According to the above arrangement, the spark detection device 400 can detect the spark signal with temperature higher than the predetermined threshold value and generate the output signal Vout according to predetermined magnitude of the threshold signal. The present invention can further generate a warning signal according to the output signal Vout.

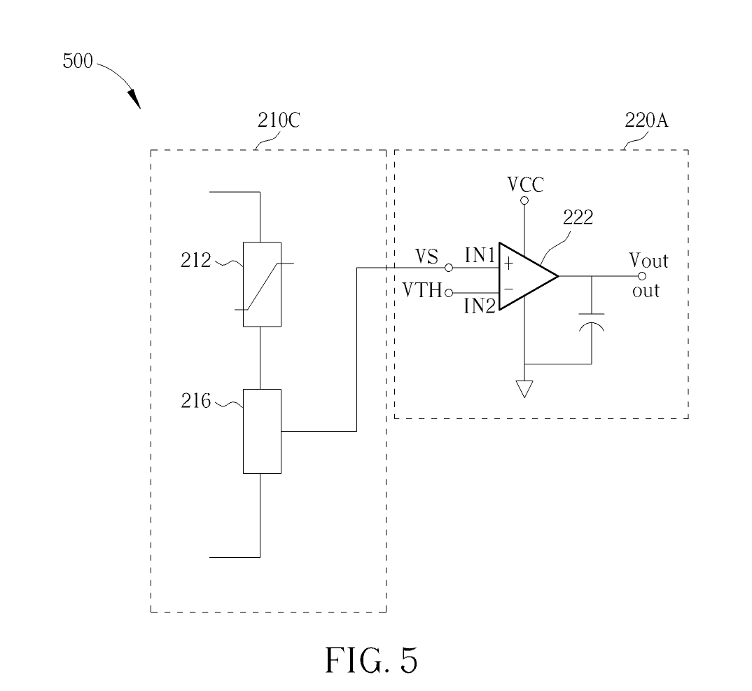

Please refer to FIG. 5. FIG. 5 is a diagram showing a fourth embodiment the spark detection device of the present invention. As shown in FIG. 5, the sensing element 210C of the spark detection device 500 comprises a spark bypass unit 212 and a current detection unit 216. The spark bypass unit 212 is for allowing the spark signal passing through. The current detection unit 216 is for generating the sensing signal VS according to a current level of the spark signal when the spark signal passing through the current detection unit 216. The comparing element 220A comprises a comparator 222. A first input end IN1 of the comparing element 220A is coupled to the current detection unit 216, and a second input end IN2 of the comparing element 220A is for receiving the threshold signal VTH. When the spark signal passes through the spark bypass unit 212, the current detection unit 216 generates a corresponding sensing signal VS. The comparing element 220A then compares the sensing signal VS with the threshold signal VTH by the comparator 222. When the sensing signal VS is greater than the threshold signal VTH, the comparing element 220A generates the output signal Vout at the output end out, for notifying occurrence of the spark signal, and the current level of the spark signal is greater than a predetermined threshold value.

According to the above arrangement, the spark detection device 500 can detect the spark signal with the current level greater than the predetermined threshold value and generate the output signal Vout according to predetermined magnitude of the threshold signal. Other spark signals with current levels smaller than the threshold value are neglected.

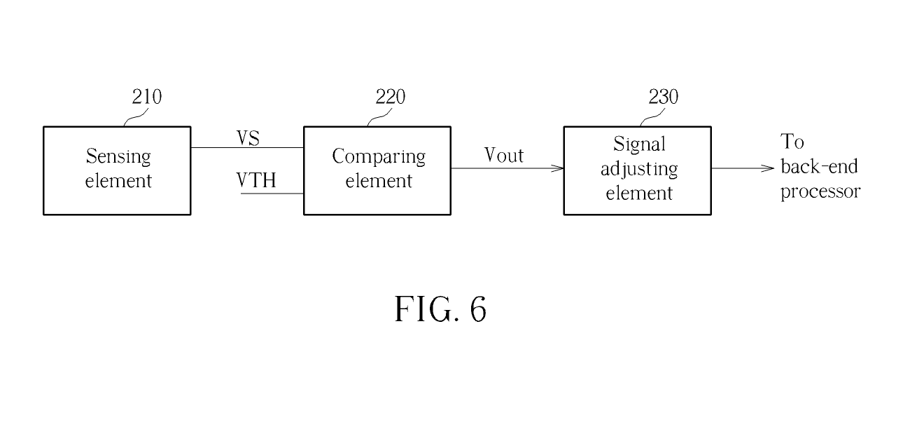

Please refer to FIG. 6. FIG. 6 is a functional block diagram of the spark detection device of the present invention. As shown in FIG. 6, besides comprising the sensing element 210 and the comparing element 220, the spark detection device of the present invention can further comprise a signal adjusting element 230 coupled to the output end of the comparing element 220, for detecting or adjusting pulse width of the output signal Vout. Since the spark signal is occurred in a very short time, the pulse width of the spark signal is very narrow. In order to make the output signal Vout readable to a back-end processor, the signal adjusting element 230 can adjust the pulse width of the output signal Vout to widen the pulse width of the output signal Vout.

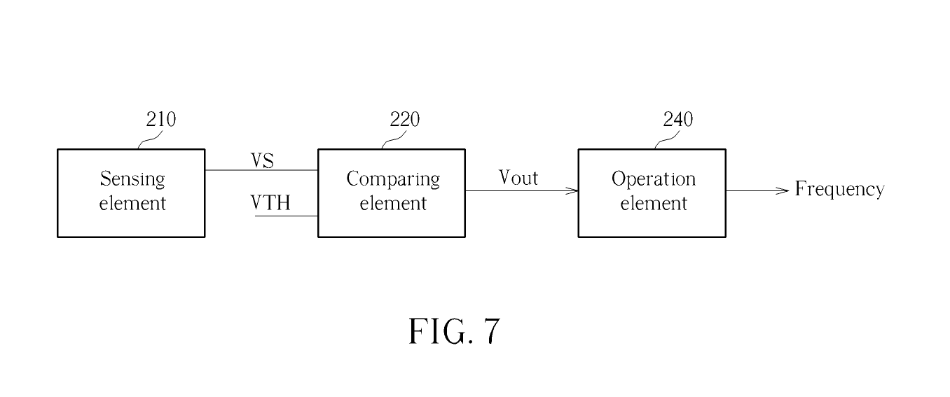

Please refer to FIG. 7. FIG. 7 is another functional block diagram of the spark detection device of the present invention. As shown in FIG. 7, besides comprising the sensing element 210 and the comparing element 220, the spark detection device of the present invention can further comprise an operation element 240 coupled to the output end of the comparing element 220 for calculating a frequency of the spark signal according to number of times the spark signal occurred per unit of time.

In addition, the above sensing elements 210A, 210B, 210C, and the above comparing elements 220A, 220B are examples for illustrating the embodiments of the present invention. In other embodiments of the present invention, the sensing elements can be composed of other types of sensing units, and the comparing elements can be replaced by other components. For example, the sensing unit of the sensing element can be an induction coil, a trace of a circuit board, a pin of a chip, a trace of a chip, or other component with induction characteristics. Moreover, the sensing elements 210A, 210B, 210C of the above embodiments can be mutually combined for detecting different characteristics of the spark signal according to design requirements.

In contrast to the prior art, the spark detection device of the present invention can utilize different types of sensing elements for sensing the spark signal, and detecting characteristics of the spark signal according to a comparing result of the comparing element. Therefore, the spark detection device of the present invention can not only detect the occurrence of the spark signal, but also detect the characteristics of voltage level, energy level and frequency of the spark signal, so as to increase flexibility during use.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A spark detection device capable of detecting characteristics of a spark signal, comprising:
a sensing element for sensing a spark signal to generate a sensing signal; and
a comparing element, a first end of the comparing element being coupled to the sensing element, a second end of the comparing element being for receiving a threshold signal, the comparing element being for generating an output signal at an output end of the comparing element by performing a comparing operation according to the sensing signal and the threshold signal.

2. The spark detection device of claim 1 further comprising a signal adjusting element coupled to the output end of the comparing element, for detecting or adjusting pulse width of the output signal.

3. The spark detection device of claim 1, wherein the comparing element comprises a comparator for comparing the sensing signal with the threshold signal to generate the output signal when the sensing signal is greater than the threshold signal.

4. The spark detection device of claim 1, wherein the comparing element comprises:
an integrator circuit for performing an integration operation to the sensing signal to generate a corresponding energy level signal; and
a comparator coupled to the integrator circuit for comparing the energy level signal with the threshold signal to generate the output signal when the energy level signal is greater than the threshold signal.

5. The spark detection device of claim 1, wherein the sensing element comprises:
a resistor coupled to a ground end; and
an electromagnetic sensing unit coupled between the resistor and a first input end of the comparator.

6. The spark detection device of claim 5, wherein the electromagnetic sensing unit can be an induction coil, a trace of a circuit board, a pin of a chip, a trace of a chip, or an component with induction characteristics.

7. The spark detection device of claim 1, wherein the sensing element comprises:
a spark bypass unit for allowing the spark signal passing through; and
a temperature sensing unit for sensing temperature of the spark bypass unit to generate the sensing signal when the spark signal passing through the spark bypass unit.

8. The spark detection device of claim 1, wherein the sensing element comprises a current detection unit for generating the sensing signal according to a current level of the spark signal when the spark signal passing through the current detection unit.

9. The spark detection device of claim 1 further comprising an operation element coupled to the output end of the comparing element for calculating a frequency of the spark signal according to number of times the spark signal occurred per unit of time.

10. The spark detection device of claim 1, wherein magnitude of the threshold signal is adjustable.
